(19) United States
(12) Patent Application Publication
(10) Pub. No.: US 2017/0155076 A1
(43) Pub. Date: Jun. 1, 2017

(54) OLED DISPLAY DEVICE AND METHOD FOR MANUFACTURING THE SAME

(71) Applicant: Shenzhen China Star Optoelectronics Technology Co., Ltd., Shenzhen, Guangdong (CN)

(72) Inventor: Chao Xu, Shenzhen, Guangdong (CN)

(73) Assignee: Shenzhen China Star Optoelectronics Technology Co., Ltd., Shenzhen, Guangdong (CN)

(21) Appl. No.: 14/786,054

(22) PCT Filed: Jul. 17, 2015
(86) PCT No.: PCT/CN2015/084328

§ 371 Date: Dec. 13, 2016

(30) Foreign Application Priority Data
Jul. 1, 2015 (CN) 201510376872.2

(51) Int. Cl. H01L 51/52; H01L 27/32; H01L 51/00

(52) U.S. Cl. CPC H01L 51/5206; H01L 51/0021; H01L 27/3248; H01L 2227/323

(57) ABSTRACT

An OLED display device and a method for manufacturing the OLED display device are disclosed. The OLED display device comprises a substrate, a TFT, a pixel electrode, a hole transport layer, an emitting material layer, an electron transport layer, and a cathode that are formed in sequence. The pixel electrode which is electrically connected with the TFT comprises a conductive metal layer and a protection layer that is formed on the conductive metal layer. According to the present disclosure, the pixel electrode is formed through electroplating procedure, and thus the manufacturing procedure of the display device can be simplified compared with the complicated sputtering procedure.

### CROSS REFERENCE TO RELATED APPLICATION

The present application claims benefit of Chinese patent application CN 201510376872.2, entitled “OLED Display Device and Method for Manufacturing the Same” and filed on Jul. 1, 2015, the entirety of which is incorporated herein by reference.

### FIELD OF THE INVENTION

The present disclosure relates to the technical field of display, and particularly to an Organic Light-Emitting Diode (OLED) display device and a method for manufacturing the OLED display device.

### BACKGROUND OF THE INVENTION

The OLED display device has the advantages of high brightness, fast response speed, low power consumption, and bendable structure. Therefore, the OLED display device is widely considered as a research focus in the display technology of next generation.

In the prior art, during the manufacturing of the OLED display device, a pixel electrode is generally formed through sputtering an Indium Tin Oxide (ITO) transparent electrode, and then a silver layer is formed on the pixel electrode. The ITO transparent electrode and the silver layer jointly constitute an anode of a top-emitting OLED display device.

The defect of the OLED display device in the prior art lies in that, the price of the ITO transparent electrode is extremely high, and thus the overall manufacturing cost of the OLED display device is increased.

### SUMMARY OF THE INVENTION

The pixel electrode of the OLED display device in the prior art is the ITO transparent electrode with an extremely high price, and thus the overall manufacturing cost of the OLED display device is increased. The present disclosure aims to solve the aforesaid technical problem.

In order to solve the aforesaid technical problem, the present disclosure provides an OLED display device and a method for manufacturing the OLED display device.

According to one aspect, the present disclosure provides an OLED display device, comprising: a substrate; a TFT that is formed on the substrate; a pixel electrode that is formed on the TFT and is electrically connected with the TFT, the pixel electrode comprising a conductive metal layer and a protection layer that is formed on the conductive metal layer; and a hole transport layer, an emitting material layer, an electron transport layer, and a cathode that are formed on the pixel electrode in sequence.

Preferably, the conductive metal layer is an aluminum (Al) layer or a silver (Ag) layer.

Preferably, the protection layer is a molybdenum (Mo) layer.

Preferably, the OLED display device further comprises a buffer layer that is formed on the pixel electrode, the hole transport layer being formed on the buffer layer.

Preferably, the buffer layer is one selected from a group consisting of an MoO₃ layer, a V₂O₅ layer, a WO₃ layer, and an NiO layer.

Preferably, the OLED display device further comprises a capping layer that is formed on the cathode.

According to another aspect, the present disclosure further provides a method for manufacturing an OLED display device, comprising the following steps: providing a substrate; forming a TFT on the substrate; forming a pixel electrode on the TFT, so that the pixel electrode is electrically connected with the TFT, the pixel electrode comprising a conductive metal layer and a protection layer that is formed on the conductive metal layer; and forming a hole transport layer, an emitting material layer, an electron transport layer, and a cathode on the pixel electrode in sequence.

Preferably, the conductive metal layer is an aluminum (Al) layer or a silver (Ag) layer; and the protection layer is a molybdenum (Mo) layer.

Preferably, the method further comprises forming a buffer layer on the pixel electrode before the hole transport layer is formed, wherein the buffer layer is one selected from a group consisting of an MoO₃ layer, a V₂O₅ layer, a WO₃ layer, and an NiO layer.

Preferably, the method further comprises forming a capping layer on the cathode.

Compared with the prior art, one embodiment or a plurality of embodiments according to the present disclosure may have the following advantages or beneficial effects.

In the OLED display device according to the present disclosure, the pixel electrode is constituted by the conductive metal layer and the protection layer that are formed on the TFT in sequence. Compared with the ITO transparent electrode that is formed through sputtering procedure in the prior art, the price of the pixel electrode according to the present disclosure is low, so that the manufacturing cost of the display device can be reduced to a large extent. Moreover, the pixel electrode is formed through electroplating procedure, and thus the manufacturing procedure of the OLED display device can be greatly simplified compared with the complicated sputtering procedure.

Other features and advantages of the present disclosure will be further explained in the following description, and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE DRAWINGS

The accompanying drawings provide further understandings of the present disclosure and constitute one part of the description. The drawings are used for interpreting the present disclosure together with the embodiments, not for limiting the present disclosure. In the drawings:

FIG. 1 schematically shows a structure of an OLED display device according to one embodiment of the present disclosure;

FIG. 2 is a flow chart of a method for manufacturing the OLED display device according to one embodiment of the present disclosure; and

FIG. 3 is another flow chart of a method for manufacturing the OLED display device according to one embodiment of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It should be noted that, as long as there is no structural conflict, all the technical features mentioned in all the embodiments may be combined together in any manner, and the technical solutions obtained in this manner all fall within the scope of the present disclosure.

The pixel electrode of the OLED display device in the prior art is the ITO transparent electrode with an extremely high price, and thus the overall manufacturing cost of the OLED display device is increased. The present disclosure aims to solve the aforesaid technical problem. In order to solve the aforesaid technical problem, the embodiment of the present disclosure provides an OLED display device with a low cost.

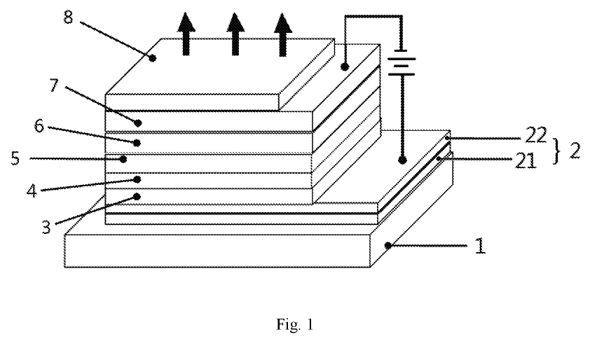

FIG. 1 schematically shows a structure of an OLED display device according to the embodiment of the present disclosure. The OLED display device according to the present embodiment mainly comprises a substrate (not shown in FIG. 1), a Thin Film Transistor (TFT) 1, a pixel electrode 2, a hole transport layer 4, an emitting material layer 5, an electron transport layer 6, and a semitransparent cathode 7.

Specifically, the TFT 1 is formed on the substrate; the pixel electrode 2 is formed on the TFT 1, and is electrically connected with a source/a drain of the TFT 1; the hole transport layer 4 is formed on the pixel electrode 2; the emitting material layer 5 is formed on the hole transport layer 4; the electron transport layer 6 is formed on the emitting material layer 5; and the semitransparent cathode 7 is formed on the electron transport layer 6. In particular, according to the present embodiment, the pixel electrode 2 is a composite electrode that is constituted by a conductive metal layer 21 and a protection layer 22 to serve as an anode of the OLED display device. The conductive metal layer 21 is formed on a passivation layer that is arranged on the TFT 1, and is electrically connected with the source/the drain of the TFT 1 through via holes arranged in the passivation layer. In general, the passivation layer is plated with a metal layer with conductivity, so as to form the conductive metal layer 21. The protection layer 22 that is formed on the conductive metal layer 21 can slow down the oxidation of the conductive metal layer 21 effectively.

It can be seen that, the OLED display device according to the present embodiment is a top-emitting display device. The light that is emitted by the emitting material layer 5, after being reflected by the pixel electrode 2, can pass through the semitransparent cathode 7 and emit out. A direction of the light emitted from the cathode 7 is shown by the arrows in FIG. 1. Here, the pixel electrode 2 (i.e., the anode) and the semitransparent cathode 7 constitute a micro-cavity structure, and thus the color saturation of the light can be improved by the micro-cavity effect. The aperture ratio of the OLED display device can be improved by the top-emitting structure.

According to the present embodiment, the pixel electrode 2 is constituted by the conductive metal layer 21 and the protection layer 22 that are formed on the TFT 1 in sequence. Compared with the ITO transparent electrode that is formed through sputtering procedure in the prior art, the price of the pixel electrode 2 according to the present embodiment is low, so that the manufacturing cost of the display device can be reduced to a large extent. Moreover, according to the present embodiment, the pixel electrode 2 is formed through electroplating procedure, and thus the manufacturing procedure of the OLED display device can be greatly simplified compared with the complicated sputtering procedure.

According to one preferred embodiment of the present disclosure, the conductive metal layer 21 is an aluminum (Al) layer or a silver (Ag) layer.

According to one preferred embodiment of the present disclosure, the protection layer 22 is a molybdenum (Mo) layer. The Mo layer can slow down the oxidation of the Al layer or the Ag layer, and thus the conductivity of the conductive metal layer 21 can be maintained.

According to one preferred embodiment of the present disclosure, the OLED display device further comprises a buffer layer 3 that is arranged between the pixel electrode 2 and the hole transport layer 4. That is, the buffer layer 3 is formed on the pixel electrode 2, and the hole transport layer 4 is formed on the buffer layer 3. Specifically, the buffer layer 3 is preferably selected to be a transparent conducting oxide layer, such as an MoO₃ layer, a V₂O₅ layer, a WO₃ layer, and an NiO layer.

According to the present embodiment, the structure of the pixel electrode 2 (i.e., the anode) is modified through adding the buffer layer 3, so that the injection ability of the holes can be improved. The role of the buffer layer 3 is to prevent the damages on the organic layer during the deposition of the electrode, and to improve the charge transmission efficiency through reducing the barrier potential during the procedure that the charges are injected from the electrode into the organic layer.

In order to improve the transmissivity of the light-exiting surface of the display device, according to one preferred embodiment of the present disclosure, the OLED display device further comprises a capping layer 8 that is formed on the semitransparent cathode 7. The capping layer 8 is preferably selected to be an Alq3 layer or an MgO layer. According to the present embodiment, the capping layer 8 serves as a refractive index matching layer. The light-exiting efficiency of the display device can be improved to a large extent through selecting the refractive index matching layer with different materials and deposition thicknesses. In addition, the capping layer 8 can also be selected to be a scattering layer, which can also improve the light-exiting efficiency of the display device.

Accordingly, the embodiment of the present disclosure further provides a method for manufacturing the OLED display device.

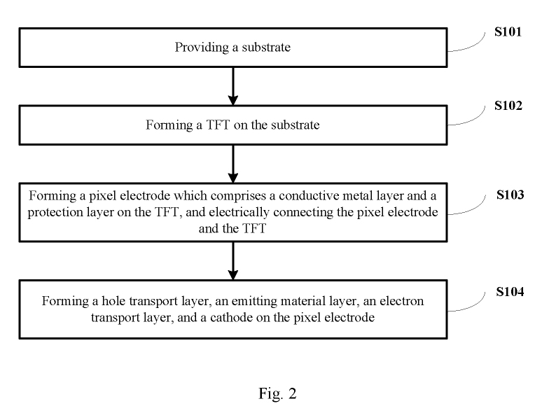

FIG. 2 is a flow chart of the method for manufacturing the OLED display device according to the embodiment of the present disclosure. The manufacturing method according to the present embodiment mainly comprises step 101 to step 104.

In step 101, a substrate is provided.

In step 102, a TFT 1 is formed on the substrate. In this step, the TFT 1 can be a bottom-gate TFT 1, or a top-gate TFT 1. The manufacturing of the TFT 1 belongs to conventional technical means in the art, and thus the details of which are no longer repeated here.

In step 103, a pixel electrode 2 is formed on the TFT 1, and is electrically connected with the TFT 1. The pixel electrode 2 comprises a conductive metal layer 21 and a protection layer 22 that is formed on the conductive metal layer 21. In this step, the conductive metal layer 21 and the protection layer 22 are both formed through electroplating procedure. Specifically, a passivation layer with via holes is formed on the TFT 1, and the conductive metal layer 21 and the protection layer 22 are formed on the passivation layer in sequence through electroplating procedure. The conductive metal layer 21 is electrically connected with a source/a drain of the TFT 1 through the aforesaid via holes. In general, the passivation layer is plated with a metal layer with conductivity so as to form the conductive metal layer 21. The protection layer 22 is formed on the conductive metal layer 21, so as to slow down the oxidation of the conductive metal layer 21 effectively.

In step 104, a hole transport layer 4, an emitting material layer 5, an electron transport layer 6, and a cathode 7 are formed on the pixel electrode 2 in sequence.

It can be seen that, the OLED display device manufactured according to the method of the present embodiment is a top-emitting display device. The light that is emitted by the emitting material layer 5, after being reflected by the pixel electrode 2, can pass through the semitransparent cathode 7 and emit out. Here, the pixel electrode 2 (i.e., the anode) and the semitransparent cathode 7 constitute a micro-cavity structure, and thus the color saturation of the light can be improved by the micro-cavity effect. The aperture ratio of the OLED display device can be improved by the top-emitting structure.

According to the present embodiment, the pixel electrode 2 is constituted by the conductive metal layer 21 and the protection layer 22 that are formed on the TFT 1 in sequence. Compared with the ITO transparent electrode that is formed through sputtering procedure in the prior art, the price of the pixel electrode 2 according to the present embodiment is low, so that the manufacturing cost of the display device can be reduced to a large extent. Moreover, according to the present embodiment, the pixel electrode 2 is formed through electroplating procedure, and thus the manufacturing procedure of the OLED display device can be greatly simplified compared with the complicated sputtering procedure.

Further, in step 103, the passivation layer is electroplated with an Al layer or an Ag layer to serve as the conductive metal layer 21. The conductive metal layer 21 is electroplated with an Mo layer to serve as the protection layer 22. The Mo layer can slow down the oxidation of the Al layer or the Ag layer effectively, so that the conductivity of the conductive metal layer 21 can be maintained.

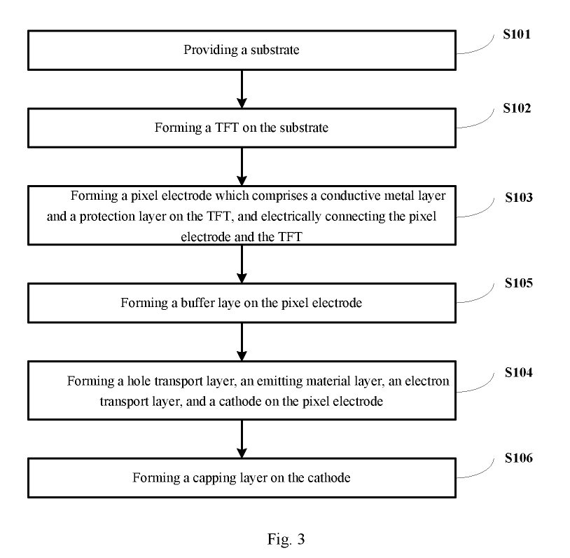

According to one preferred embodiment of the present disclosure, as shown in FIG. 3, step 105 is added between the step 103 and the step 104. In step 105, a buffer layer 3 is formed on the pixel electrode 2. Specifically, the buffer layer 3 is preferably selected to be a transparent conducting oxide layer, such as an MoO₃ layer, a V₂O₅ layer, a WO₃ layer, and an NiO layer.

According to the present embodiment, the structure of the pixel electrode 2 (i.e., the anode) is modified through adding the buffer layer 3, and the injection ability of the holes can be improved. The role of the buffer layer 3 is to prevent the destroy on the organic layer during the deposition of the electrode, and to improve the charge transmission efficiency through reducing the barrier potential during the process that the charges are injected from the electrode into the organic layer.

As shown in FIG. 3 again, in order to improve the transmissivity of the light-exiting surface of the display device, according to one preferred embodiment of the present disclosure, the method further comprises step 106. In step 106, a capping layer 8 is formed on the cathode 7. The capping layer 8 is preferably selected to be an Alq3 layer or an MgO layer. According to the present embodiment, the capping layer 8 serves as a refractive index matching layer. The light-exiting efficiency of the display device can be improved to a large extent through selecting the refractive index matching layer with different materials and deposition thicknesses. In addition, the capping layer 8 can also be selected to be a scattering layer, which can also improve the light-exiting efficiency of the display device.

The above embodiments are described only for better understanding, rather than restricting, the present disclosure. Any person skilled in the art can make amendments to the implementing forms or details without departing from the spirit and scope of the present disclosure. The protection scope of the present disclosure shall be determined by the scope as defined in the claims.

1. An OLED display device, comprising:
a substrate;
a TFT that is formed on the substrate;
a pixel electrode that is formed on the TFT and is electrically connected with the TFT, the pixel electrode comprising a conductive metal layer and a protection layer that is formed on the conductive metal layer; and
a hole transport layer, an emitting material layer, an electron transport layer, and a cathode that are formed on the pixel electrode in sequence.

2. The OLED display device according to claim 1, further comprising a buffer layer that is formed on the pixel electrode, the hole transport layer being formed on the buffer layer.

3. The OLED display device according to claim 2, wherein the buffer layer is one selected from a group consisting of an MoO₃ layer, a V₂O₅ layer, a WO₃ layer, and an NiO layer.

4. The OLED display device according to claim 3, further comprising a capping layer that is formed on the cathode.

5. The OLED display device according to claim 1, wherein the conductive metal layer is an aluminum (Al) layer or a silver (Ag) layer.

6. The OLED display device according to claim 5, further comprising a buffer layer that is formed on the pixel electrode, the hole transport layer being formed on the buffer layer.

7. The OLED display device according to claim 6, wherein the buffer layer is one selected from a group consisting of an MoO₃ layer, a V₂O₅ layer, a WO₃ layer, and an NiO layer.

8. The OLED display device according to claim 7, further comprising a capping layer that is formed on the cathode.

9. The OLED display device according to claim 5, wherein the protection layer is a molybdenum (Mo) layer.

10. The OLED display device according to claim 9, further comprising a buffer layer that is formed on the pixel electrode, the hole transport layer being formed on the buffer layer.

11. The OLED display device according to claim 10, wherein the buffer layer is one selected from a group consisting of an MoO₃ layer, a V₂O₅ layer, a WO₃ layer, and an NiO layer.

12. The OLED display device according to claim 11, further comprising a capping layer that is formed on the cathode.

13. A method for manufacturing an OLED display device, comprising the following steps:
providing a substrate;
forming a TFT on the substrate;
forming a pixel electrode on the TFT, so that the pixel electrode is electrically connected with the TFT, the pixel electrode comprising a conductive metal layer and a protection layer that is formed on the conductive metal layer; and
forming a hole transport layer, an emitting material layer, an electron transport layer, and a cathode on the pixel electrode in sequence.

14. The method according to claim 13, further comprising forming a buffer layer on the pixel electrode before the hole transport layer is formed, wherein the buffer layer is one selected from a group consisting of an MoO₃ layer, a V₂O₅ layer, a WO₃ layer, and an NiO layer.

15. The method according to claim 14, further comprising forming a capping layer on the cathode.

16. The method according to claim 13, wherein the conductive metal layer is an aluminum (Al) layer or a silver (Ag) layer; and
wherein the protection layer is a molybdenum (Mo) layer.

17. The method according to claim 16, further comprising forming a buffer layer on the pixel electrode before the hole transport layer is formed, wherein the buffer layer is one selected from a group consisting of an MoO₃ layer, a V₂O₅ layer, a WO₃ layer, and an NiO layer.

18. The method according to claim 17, further comprising forming a capping layer on the cathode.
